(19) United States
(12) Patent Application Publication
(10) Pub. No.: US 2008/0093677 A1
(43) Pub. Date: Apr. 24, 2008

(54) SEMICONDUCTOR DEVICES AND METHODS OF FABRICATING THE SAME

(75) Inventors: Tae Kyung Kim, Seoul (KR); Sung-Hoi Hur, Seoul (KR); Chang-Sub Lee, Gyeonggi-do (KR); Seung-Chul Lee, Gyeonggi-do (KR); Dong-Jun Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/616,947

(22) Filed: Dec. 28, 2006

(30) Foreign Application Priority Data
Oct. 20, 2006 (KR) 2006-102573

(51) Int. Cl. H01L 29/76; H01L 29/94; H01L 31/00; H01L 21/8238

(52) U.S. Cl. 257/390; 438/231

(57) ABSTRACT

Provided are semiconductor devices and methods of fabricating the same. A semiconductor device may include a semiconductor substrate with a device isolation layer defining HVE and HVD active regions. Gate insulation layer patterns may be disposed on the HVE and HVD active regions. Gate electrodes may be disposed on the gate insulation layer patterns to intersect the HVE and HVD active regions and the device isolation layer. An ion implantation layer may be disposed on the semiconductor substrate under the gate electrode of the HVD active region, spaced apart from the device isolation layer, and serves to adjust a threshold voltage.

### CROSS-REFERENCE TO RELATED APPLICATIONS

This U.S. non-provisional patent application claims priority under 35 U.S.C. § 119 to copending Korean Patent Application No. 2006-102573, filed on Oct. 20, 2006, the entire contents of which are hereby incorporated by reference.

### BACKGROUND OF THE INVENTION

The present invention disclosed herein relates to semiconductor devices and methods of fabricating the same, and more particularly, to high-voltage semiconductor devices and methods of fabricating the same.

In general, semiconductor memory devices may be classified into volatile memory devices and nonvolatile memory devices. The volatile memory devices may require a power supply to retain data, while the nonvolatile memory devices can retain data without power. A flash memory device may be a highly-integrated nonvolatile memory device that may be developed to be provide the benefits of both an erasable programmable read only memory (EPROM) and an electrically erasable programmable read only memory (EEPROM).

The flash memory device may have a high-voltage (HV) transistor in a peripheral region. The HV transistor may require a high breakdown voltage (BV). The high BV may be provided by thickening a gate insulation layer of the high-voltage transistor. However, a thick gate insulation layer may increase a body effect that may cause a change in a threshold voltage (Vth).

Reference is now made to FIGS. 1A and 1B, which are a plan view of a conventional high-voltage semiconductor device and a sectional view taken along a line I-I′ of the same. The conventional high-voltage semiconductor device may include a semiconductor substrate 10, a device isolation layer 11 defining an HV enhancement (HVE) active region 12e and an HV depletion (HVD) active region 12d, an ion implantation layer 14d disposed on the entire surface of the semiconductor substrate 10 of the HDV active region 12d to adjust a threshold voltage (Vth), gate insulation layer patterns 16e and 16d disposed on the HVE active region 12e and the HVD active region 12d, and gate electrodes 18e and 18d disposed on the gate insulation layer patterns 16e and 16d a to intersect the HVE and HVD active regions 12e and 12d and the device isolation layer 11.

A device isolation ion implantation layer (not illustrated) may be disposed in the semiconductor substrate 10 under the device isolation layer 11. A count ion implantation layer 13c may be disposed in the semiconductor substrate 10 of the HVD active region 12d. Enhancement ion implantation layers 15e may be disposed in the semiconductor substrate 10 of the HVE and HVD active regions 12e and 12d. Low-concentration source/drain regions 21els, 21dls, 21eld and 21dld may be disposed on the both sides of gate electrodes 18e and 18d in the HVE and HVD active regions 12e and 12d. High-concentration source/drain regions 23ehs, 23dhs, 23ehd and 23dhd may be disposed in the low-concentration source/drain regions 21els, 21dls, 21eld and 21dld, respectively.

In addition, contact plugs 24e and 24d may be disposed on the high-concentration source/drain regions 23ehs, 23dhs, 23ehd and 23dhd. Capping layers 20e and 20d may also be disposed on the gate electrodes 18e and 18d. An interlayer insulating layer 22 may also be provided for forming the contact plugs 24e and 24d.

A high electric field may be generated at the edge of the gate electrode and the edge of the active region adjacent to the device isolation layer, which may reduce the breakdown voltage (BV) of the conventional high-voltage semiconductor device. In addition, high electric fields may be generated between the contact plugs and the edge of the active region and/or between the contact plugs and the edge of the gate electrode, which also may reduce the breakdown voltage.

### SUMMARY OF THE INVENTION

Embodiments of the present invention provide semiconductor devices that include: a device isolation layer, formed on a semiconductor substrate, configured to define a first active region and a second active region; multiple gate insulation layer patterns each disposed on the first and second active regions; multiple gate electrodes disposed on respective ones of the gate insulation layer patterns and configured to intersect the first and second active regions and the device isolation layer; and an ion implantation layer disposed on the semiconductor substrate under the gate electrode of the second active region and spaced apart from the device isolation layer, the ion implantation layer configured to adjust a threshold voltage. In some embodiments, the first active region may be a high-voltage enhancement active region. In some embodiments, the second active region may be a high-voltage depletion active region.

In some embodiments, the semiconductor devices further include a device isolation ion implantation layer disposed in the semiconductor substrate under the device isolation layer. The device isolation ion implantation layer may contain impurity ions with a conductivity type substantially identical to that of the semiconductor substrate.

In some embodiments, the ion implantation layer is spaced apart from the device isolation layer in at least one of the longitudinal and transverse directions from the gate electrode. The ion implantation layer may contain impurity ions with a conductivity type substantially different from that of the semiconductor substrate.

In further embodiments, the semiconductor devices may include low-concentration source/drain regions disposed on the both sides of the gate electrodes in the first and second active regions.

In some embodiments, the semiconductor devices may include high-concentration source/drain regions disposed in the low-concentration source/drain regions, respectively.

In some embodiments, the semiconductor devices may further include contact plugs disposed on the high-concentration source/drain regions. The contact plugs may be provided in numbers corresponding to the size of the ion implantation layer.

Some embodiments of the invention include methods of fabricating semiconductor devices. Such methods may include forming a device isolation layer defining first and second active regions in a semiconductor substrate and forming an ion implantation layer at a portion of the surface of the semiconductor substrate in the second active region, the ion implantation layer being spaced apart from the device isolation layer and configured to adjust a threshold voltage. Methods may also include forming gate insulation layer patterns on the first and second active regions and forming gate electrodes intersecting the first and second active regions and the device isolation layer on the gate insulation layer patterns, wherein the ion implantation layer is disposed under the gate electrode of the second active region. In some embodiments, the first active region may be a high-voltage enhancement region. In some embodiments, the second active region may be a high-voltage depletion region.

In some embodiments, methods may further include forming a device isolation ion implantation layer in the semiconductor substrate under the device isolation layer. The device isolation ion implantation layer may contain impurity ions with a conductivity type substantially identical to that of the semiconductor substrate.

In some embodiments, the ion implantation layer is spaced apart from the device isolation layer in at least one of the longitudinal and transverse directions from the gate electrode. The ion implantation layer may contain impurity ions with a conductivity type substantially different from that of the semiconductor substrate.

In further embodiments, the methods may further include forming low-concentration source/drain regions on the both sides of the gate electrodes in the first and second active regions.

In some embodiments, the methods may further include forming high-concentration source/drain regions in the low-concentration source/drain regions, respectively.

In some embodiments, the methods may further include forming contact plugs on the high-concentration source/drain regions. In some embodiments, the contact plugs may be provided in a quantity corresponding to the size of the ion implantation layer.

### BRIEF DESCRIPTION OF THE FIGURES

The components in the drawings are not necessarily to scale, emphasis instead being placed upon clearly illustrating the principles of the present disclosure. Moreover, in the drawings, like reference numerals designate corresponding parts throughout the several views.

FIG. 1A is a plan view illustrating a conventional high-voltage semiconductor device.

FIG. 1B is a sectional view taken along a line I-I′ of FIG. 1A.

FIGS. 2A and 2B are plan views of semiconductor devices according embodiments of the present invention.

FIG. 3A is a plan view of a high-voltage semiconductor device according to embodiments of the present invention.

FIG. 3B is a sectional view taken along a line II-II′ of FIG. 3A.

FIG. 4A is a plan view illustrating a high-voltage semiconductor device according to other embodiments of the present invention and methods of fabricating the same.

FIG. 4B is a sectional view taken along a line III-III′ of FIG. 4A.

FIG. 5 is a characteristic graph of a high-voltage semiconductor device according to embodiments of the present invention.

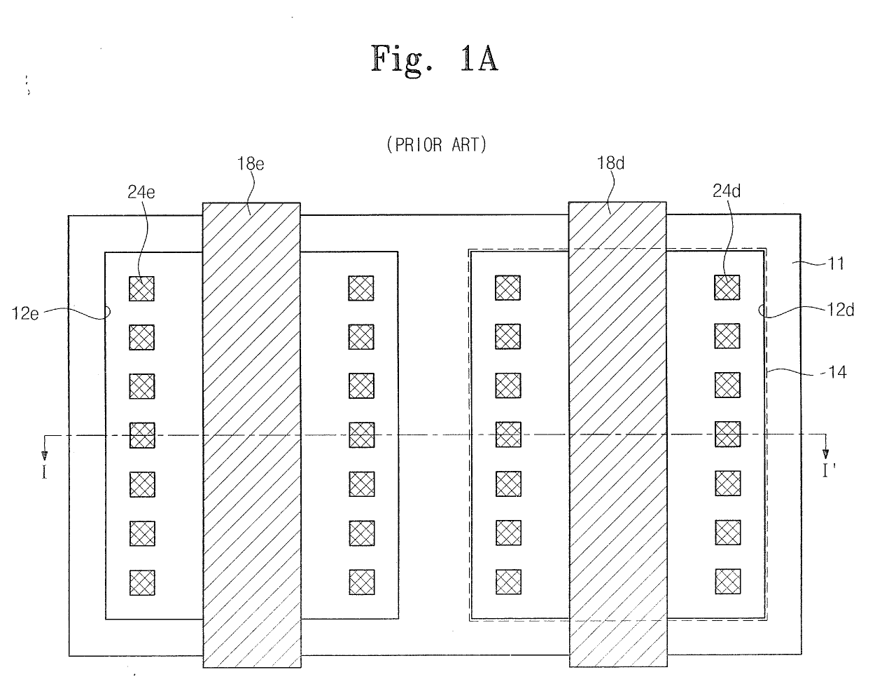

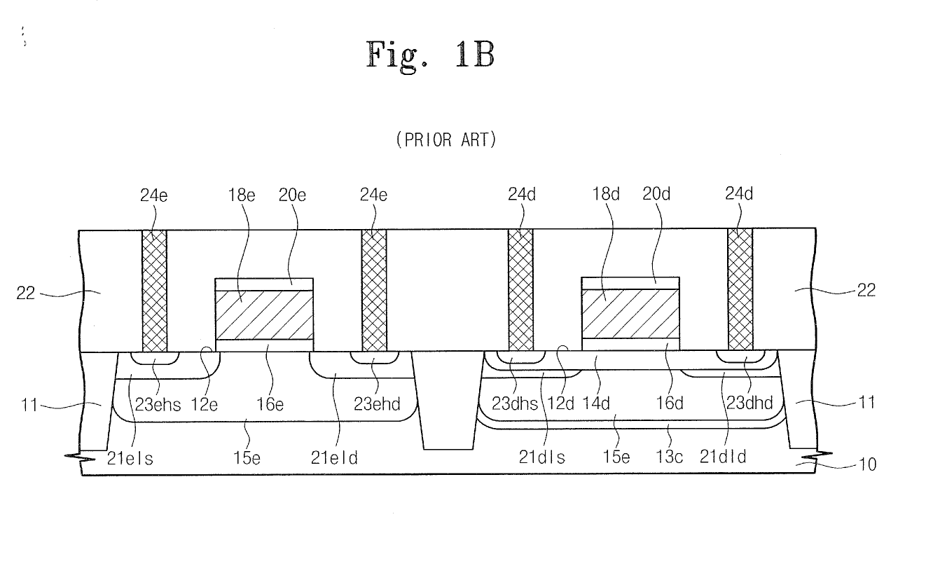

### DETAILED DESCRIPTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

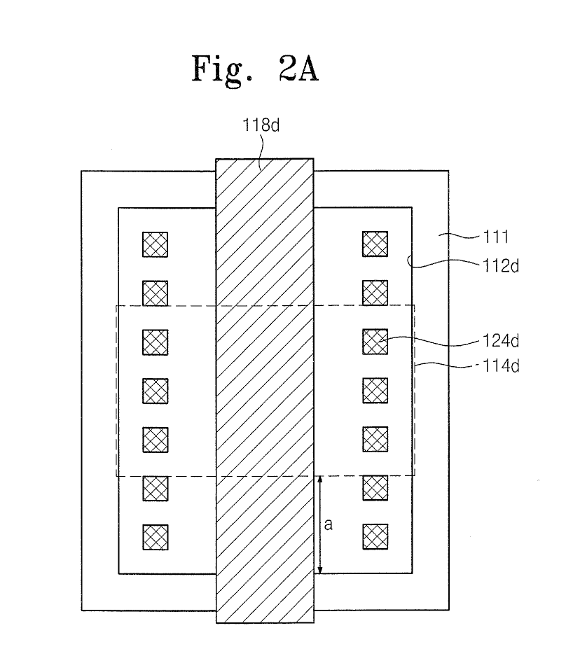

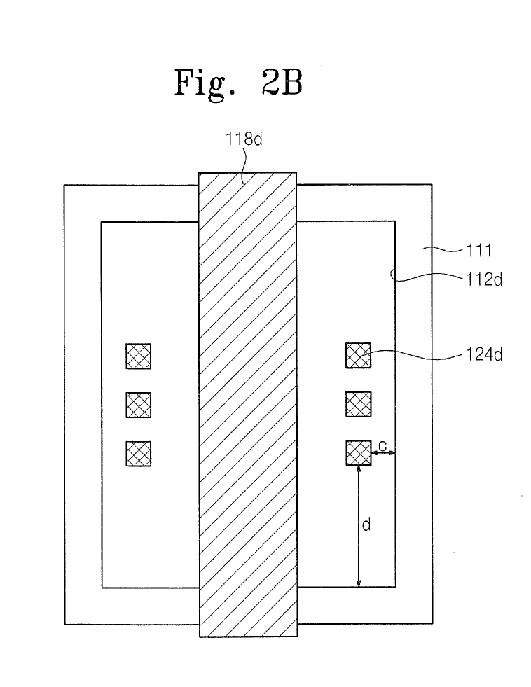

Reference is now made to FIGS. 2A and 2B, which are plan views of semiconductor devices according embodiments of the present invention. By way of example, a high-voltage depletion (HVD) active region is illustrated. Referring to FIG. 2A, an ion implantation layer 114d that can provide for adjustment of a threshold voltage (Vth) (hereinafter simply referred to as “ion implantation layer”) is spaced apart from a device isolation layer 111 by a distance “a” in the longitudinal direction of a gate electrode 118d. This can prevent a decrease in a gate induced breakdown voltage (GIBV) that may be generated at an overlap between the device isolation layer 111 and the gate electrode 118d. Further, if the ion implantation layer 114d is also spaced apart from the device isolation layer 111 by a predetermined distance in the transverse direction of the gate electrode 118d, a gate induced drain leakage (GIDL) current in a region under the edge of the gate electrode 118d may decrease. This may increase the breakdown voltage of an HVD transistor. Additionally, if the ion implantation layer 114d is spaced apart from contact plugs 124d, a high electric field may be prevented from being formed between the contact plugs 124d and the edge of the gate electrode 118d. This may increase the breakdown voltage of the HVD transistor.

Referring to FIG. 2B, some of the contact plugs 124d may be removed such that the contact plugs 124d may become distant from the edge of the HVD active region 112d. Accordingly, the contact plugs 124d may be spaced apart from the device isolation layer 111 by a distance “d” in the longitudinal direction of the gate electrode 118d. As the distance “d” becomes greater than a distance “c” (the pitch of the contact plugs 124d), a high electric field may be prevented from being formed between the contact plugs 124d and the edge of the HVD active region 112d. This can increase the breakdown voltage of the HVD transistor.

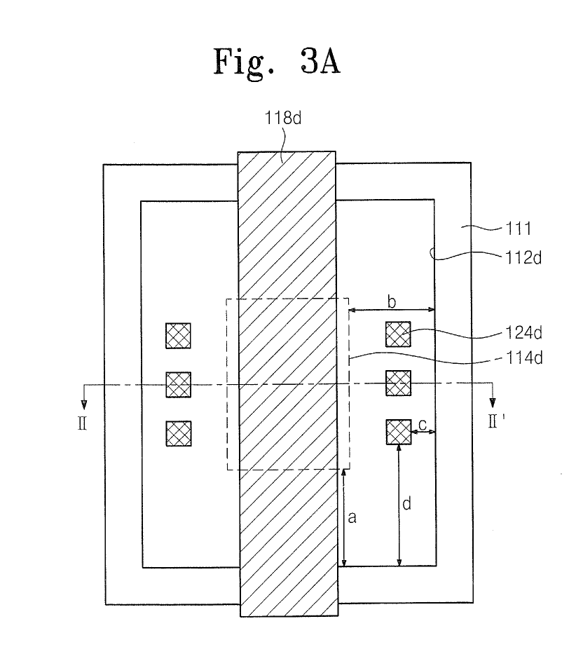

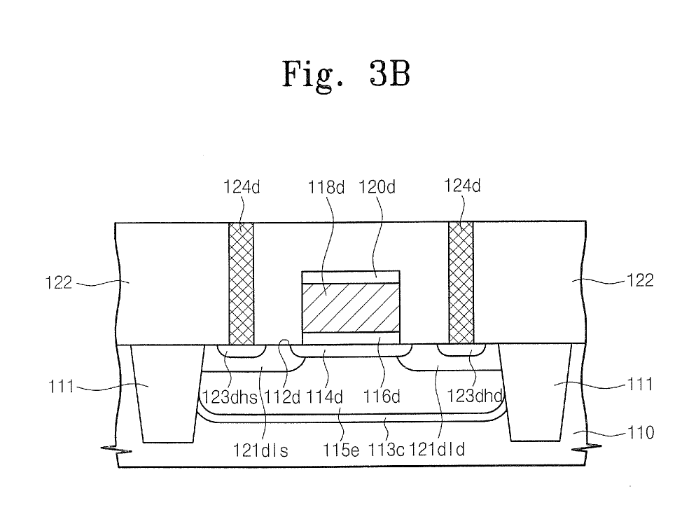

Reference is now made to FIGS. 3A and 3B, which are a plan view of a high-voltage semiconductor device and a sectional view taken along a line II-II′, respectively, according to some embodiments of the present invention. The high-voltage semiconductor device may include a semiconductor substrate 110 and a device isolation layer 111 defining an HVD (high-voltage depletion) active region 112d. A gate insulation layer pattern 116d may be disposed on the HVD active region 112d and a gate electrode 118d may be disposed on the gate insulation layer pattern 116d such that the gate electrode 118d intersects the HVD active region 112d and the device isolation layer 111. An ion implantation layer 114d may be disposed on the surface of the semiconductor substrate 110 under the gate electrode 118d of the HVD active region 112d such that it is spaced apart from the device isolation layer 111. The ion implantation layer 114d may function to adjust a threshold voltage. The ion implantation layer 114d may contain impurity ions with a conductivity type different from that of the semiconductor substrate 110.

The high-voltage semiconductor device may further include a device isolation ion implantation layer (not illustrated) disposed in the semiconductor substrate 110 under the device isolation layer 111, an enhancement ion implantation layer 115e and a count ion implantation layer 113c disposed in the semiconductor substrate 110 of the HVD active region 112d. The device may include low-concentration source/drain regions 121dls and 121dld disposed on the both sides of a gate electrode 118d in the HVD active region 112d and high-concentration source/drain regions 123dhs and 123dhd disposed in the low-concentration source/drain regions 121dls and 121dld, respectively. The device isolation ion implantation layer may contain impurity ions with a conductivity type substantially identical to that of the semiconductor substrate 110.

In addition, the high-voltage semiconductor device may further include contact plugs 124d disposed on the high-concentration source/drain regions 123dhs and 123dhd. A capping layer 120d may be provided on the gate electrode 118d. An interlayer insulating layer 122 may be provided for forming the contact plugs 124d.

Unlike the prior art, the ion implantation layer 114d is spaced apart from the device isolation layer 111 by a distance “a” in the longitudinal direction of the gate electrode 118d and by a distance “b” in the transverse direction of the gate electrode 118d. Accordingly, a GIDL current in a region under the edge of the gate electrode 118d can decrease and thus the breakdown voltage of an HVD transistor can increase. Additionally, a decrease in a GIBV that is generated at an overlap between the device isolation layer 111 and the gate electrode 118d may be prevented. Moreover, because the ion implantation layer 114d is spaced apart from also the device isolation layer 111, a high electric field may be prevented from forming between the contact plugs 124d and the edge of the gate electrode 118d. As a result, the breakdown voltage of the HVD transistor may be increased.

Additionally, the quantity of contact plugs 124d may be reduced corresponding to the size of the ion implantation layer 114d. Accordingly, the contact plugs 124d can be spaced apart from the device isolation layer 11 by a distance “d” in the longitudinal direction of the gate electrode 118d. As the distance “d” becomes greater than a distance “c” (the pitch of the contact plugs 124d), formation of a high electric field between the contact plugs 124d and the edge of the HVD active region 112d may be prevented. As a result, the breakdown voltage of the HVD transistor may be increased.

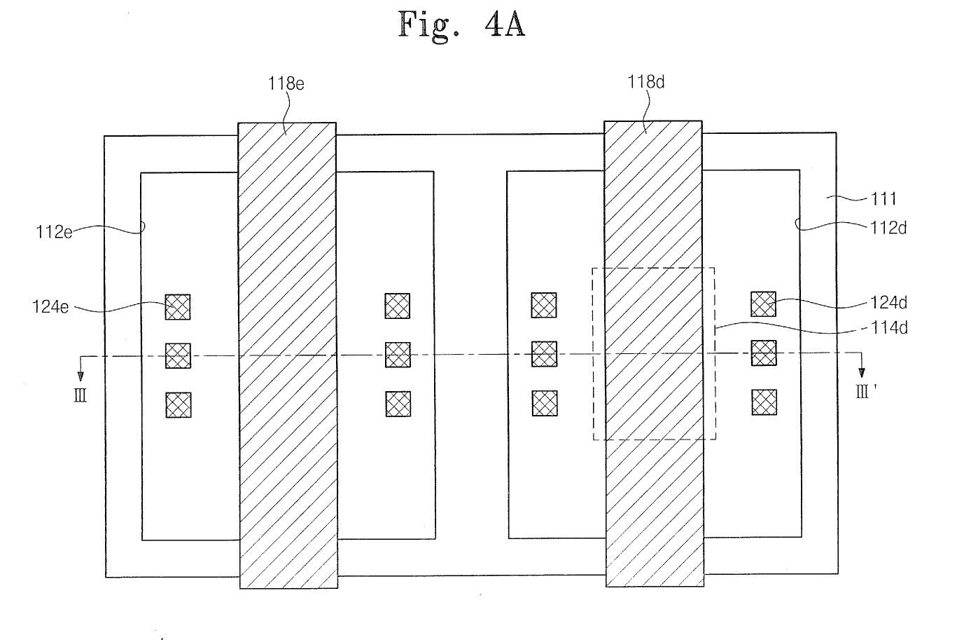

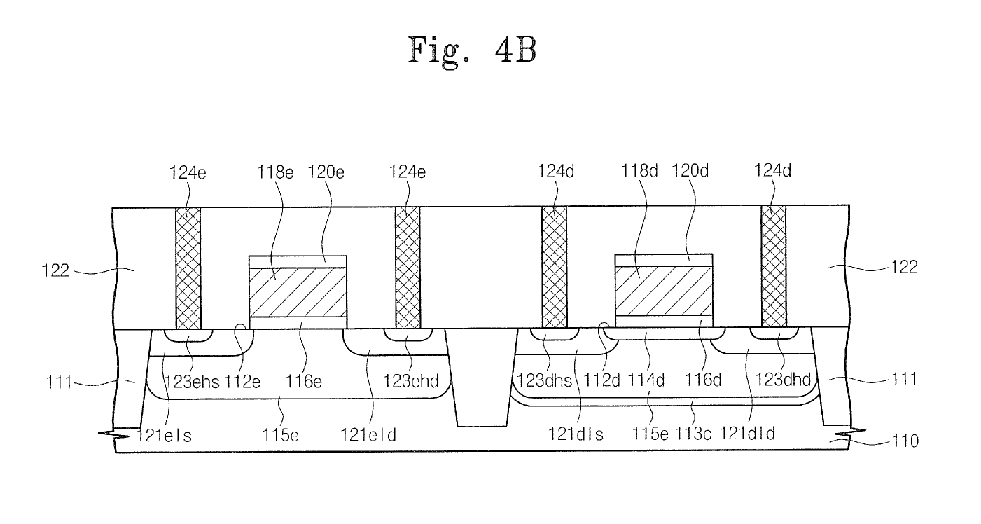

FIG. 4A is a plan view illustrating a high-voltage semiconductor device according to another embodiment of the present invention and a method of fabricating the same. FIG. 4B is a sectional view taken along a line III-III′ of FIG. 4A.

Reference is now made to FIGS. 4A and 4B, which are a plan view illustrating a high-voltage semiconductor device according to other embodiments of the present invention and methods of fabricating the same and a sectional view taken along a line III-III′, respectively. The high-voltage semiconductor device includes a semiconductor substrate 110 and a device isolation layer 111 defining an HVE (high-voltage enhancement) active region 112e and an HVD (high-voltage depletion) active region 112d. Gate insulation layer patterns 116e and 116d may be disposed on the HVE active region 112e and the HVD active region 112d and gate electrodes 118e and 118d may be disposed on the gate insulation layer patterns 116e and 116d. The gate electrode 118e may be configured to intersect the HVE active region and the device isolation layer 111. The gate electrode 118d may be configured to intersect the HVD active region 112d and the device isolation layer 111. An ion implantation layer 114d may be disposed on the surface of the semiconductor substrate 110 under the gate electrode 118d of the HVD active region 112d such that it is spaced apart from the device isolation layer 1. The ion implantation layer 114d may be used to adjust a threshold voltage. The ion implantation layer 114d may contain impurity ions with a conductivity type substantially different from that of the semiconductor substrate 110.

The high-voltage semiconductor device may further include a device isolation ion implantation layer (not illustrated) disposed in the semiconductor substrate 110 under the device isolation layer 111 and a count ion implantation layer 113c disposed in the semiconductor substrate 110 of the HVD active region 112d. Enhancement ion implantation layers 115e may be disposed in the semiconductor substrate 110 of the HVE and HVD active regions 112e and 112d. Low-concentration source/drain regions 121els, 121dls, 121eld and 121dld may be disposed on the both sides of gate electrodes 118e and 118d in the HVE and HVD active regions 112e and 112d. High-concentration source/drain regions 123ehs, 123dhs, 123ehd and 123dhd may be disposed in the low-concentration source/drain regions 121els, 121dls, 121eld and 121dld, respectively. The device isolation ion implantation layer may contain impurity ions with a conductivity type that is substantially identical to that of the semiconductor substrate 110.

In addition, the high-voltage semiconductor device may further include contact plugs 124e and 124d disposed on the high-concentration source/drain regions 123ehs, 123dhs, 123ehd and 123dhd. The contact plugs 124d may be provided in quantities corresponding to the size of the ion implantation layer 114d. Capping layers 120e and 120d may be disposed on the gate electrodes 118e and 118d. An interlayer insulating layer 122 may be disposed for forming the contact plugs 124e and 124d.

Some embodiments of the invention may also be methods of fabricating a high-voltage semiconductor device. In some such methods, a device isolation layer 111 may be formed on a semiconductor substrate 110 to define an HVE active region 112e and an HVD active region 112d. While forming the device isolation layer 111, a device isolation ion implantation layer (not illustrated) may be formed in the semiconductor substrate 110 under the device isolation layer 111. The device isolation ion implantation layer may contain impurity ions with a conductivity type that is substantially identical to that of the semiconductor substrate 110. For example, if the semiconductor substrate is P type, the device isolation ion implantation layer may be formed to a depth of 4,000 Å by an ion implantation process in which boron (B) may be used as the impurity ions. The boron implantation process may be performed at an implantation energy of 210 keV at an implantation concentration of 6.0×10¹² atoms/cm², for example.

An ion implantation layer 114d, that may be provided for adjustment of a threshold voltage, may be formed at a portion of the surface of the semiconductor substrate 110 in the HVD active region 112d that may be spaced apart from the device isolation layer 111. The ion implantation layer 114d may contain impurity ions with a conductivity type that is substantially different from that of the semiconductor substrate 110. For example, if the semiconductor substrate is P type, the ion implantation layer 114d may be formed to a depth of 540 Å by an ion implantation process in which arsenic (As) may be used as the impurity ion. The arsenic implantation process may be performed at an implantation energy of 80 keV at an implantation concentration of 1.2×10¹² atoms/cm², for example.

The ion implantation layer 114d of the HVD active region 112d may be spaced apart from the device isolation layer 111 and contact plugs 124d and is formed under a gate electrode 118d. This can improve the breakdown voltage of a HVD transistor. If the ion implantation layer 114d decreases in size along the longitudinal and transverse directions of the gate electrode 118d, the breakdown voltage of the HVD transistor can increase by about 2 V. In addition, it is possible to prevent a decrease in a GIBV that is generated at an overlap between the device isolation layer 111 and the gate electrode 118d.

Prior to forming the ion implantation layer 114d, a count ion implantation layer 113c may be formed in the semiconductor substrate 110 of the HVD active region 112d. For example, if the semiconductor substrate is P type, the count ion implantation layer 113c may be formed to a depth of 1,600 Å by an ion implantation process in which phosphorus (P) may be used as impurity ions. The phosphorous implantation process may be performed at an implantation energy of 120 keV at an implantation concentration is 112×10¹² atoms/cm², for example.

After forming the ion implantation layer 114d, an HVE ion implantation layer 115e may be formed in the semiconductor substrate 110 of the HVE and HVD active regions 112e and 112d. For example, if the semiconductor substrate is P type, the HVE ion implantation layer 113e may be formed to a depth of 1,440 Å by an ion implantation process in which boron (B) may be used as impurity ions. The boron implantation process may be performed at an implantation energy of 40 keV, at an implantation concentration of 1.7×10¹² atoms/cm², for example.

In some embodiments, the device isolation layer 111 and the device isolation ion implantation layer may be formed after forming the count ion implantation layer 113c, the ion implantation layer 114d and the HVE ion implantation layer 115e.

Gate insulation layer patterns 116e and 116e may be formed on the HVE and HVD active regions 112e and 112d. In some embodiments, the gate insulation layer patterns 116e and 116d may be a thermal oxide layer having a thickness of about 350 Å.

Gate electrodes 118e and 118d may be formed on the gate insulation layer patterns 116e and 116d. Gate electrode 118e may be configured to intersect the HVE active region 112e and the device isolation layer. Similarly, gate electrode 118d may be configured to intersect the HVD active region 112d and the device isolation layer 111. Accordingly, the ion implantation layer 114d may be disposed under the gate electrode 118d in the HVD active region 112d. In some embodiments, the gate electrodes 118e and 118d may be a doped polysilicon layer.

Low-concentration source/drain regions 121els, 121dls, 121eld and 121dld are formed on the both sides of the gate electrodes 118e and 118d in the HVE and HVD active regions 112e and 112d. For example, if the semiconductor substrate is P type, the low-concentration source/drain regions 121els, 121dls, 121eld and 121dld may be formed to a depth of 400 Å by an ion implantation process in which phosphorus (P) may be used as impurity ions. The phosphorous implantation process may be performed at an implantation energy of 35 keV at an implantation concentration is 6.0×10¹² atoms/cm², for example. High-concentration source/drain regions 123ehs, 123dhs, 123ehd and 123dhd may be formed in the low-concentration source/drain regions 121els, 121dls, 121eld and 121dld, respectively. The high-concentration source/drain regions 123ehs, 123dhs, 123ehd and 123dhd may be formed to a smaller depth at a higher implantation concentration than the low-concentration source/drain regions 121els, 121dls, 121eld and 121dld.

An interlayer insulating layer 122 may be formed to cover the semiconductor substrate 110 including the gate electrodes 118e and 118d. The interlayer insulating layer 122 may be a silicon oxide (SiO₂) layer. The interlayer insulating layer 122 may be patterned to form openings that expose the high-concentration source/drain regions 123ehs, 123dhs, 123ehd and 123dhd. Contact plugs 124e and 124d may be formed to fill the openings. The contact plugs 124e and 124d may be formed in quantities corresponding to the size of the ion implantation layer 114d. When the quantity of the contact plugs 124e and 124d is reduced corresponding to the size of the ion implantation layer 114d, the breakdown voltages of HVE and HVD transistors may be improved. If the quantity of the contact plugs 124e and 124d is reduced by three in the longitudinal direction of the gate electrodes 118e and 118d, the breakdown voltages of the HVE and HVD transistors may be increased by about 3 V.

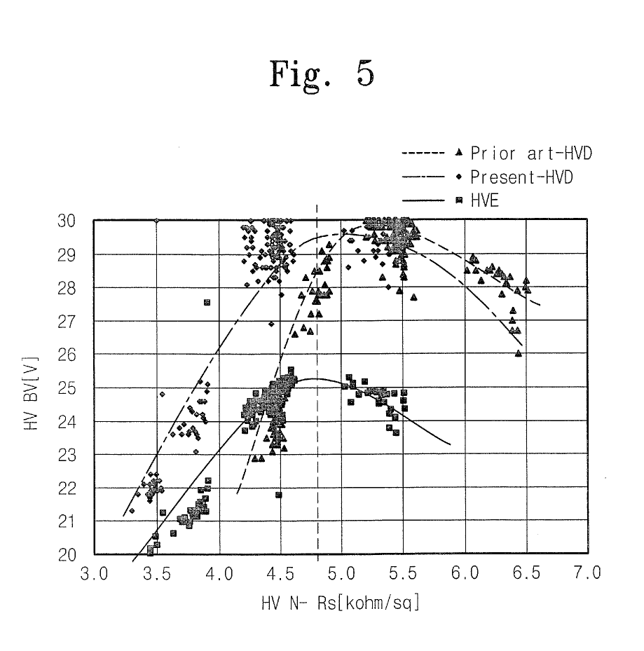

Reference is now made to FIG. 5, which is a characteristic graph of a high-voltage semiconductor device according to some embodiments of the invention. The characteristic graph illustrates the relationship between the breakdown voltage (HV BV) of the transistors in the HVE and HVD active regions of the high-voltage semiconductor device and the surface resistance (HV N-Rs) of the source/drain regions.

The ion implantation layer of the HVD active region may be spaced apart from the device isolation layer and may be formed in the semiconductor substrate under the gate electrode. In this case, although the low-concentration source/drain regions of the HVD and HVE active regions may be formed simultaneously, the junction of the HVD active region may have a similar structure to the junction of the HVE active region. Accordingly, the surface resistances of the source/drain regions, which may indicate the maximum breakdown voltages of the HVE and HVD transistors formed on the same semiconductor substrate, may have similar values (indicated by a dotted line). Consequently, it is possible to establish maximum breakdown voltages of the HVE and HVD transistors (indicated by a dotted line) using a process of forming the same source/drain region.

Using methods according to embodiments of the present invention, the ion implantation layer of the HVD active region may be spaced apart from the device isolation layer or the contact plugs and may be formed under the gate electrode. In this case, it is possible to provide semiconductor devices with improved BV characteristics and methods of fabricating the same. In addition, the quantity of the contact plugs may be reduced corresponding to the size of the ion implantation layer. Accordingly, semiconductor devices with improved BV characteristics and methods of fabricating the same may be provided.

Moreover, the ion implantation layer of the HVD active region may be spaced apart from the device isolation layer and the contact plugs and may be formed under the gate electrode. In this case, the junctions of the HVD and HVE active regions may have similar structures. Accordingly, the source/drain regions of two types of transistors with different threshold voltages may be formed simultaneously. Consequently, it is possible to provide methods of fabricating semiconductor devices using a reduced number of processes.

As described above, because the ion implantation layer of the HVD active region may be spaced apart from the device isolation layer and/or the contact plugs and may be formed under the gate electrode, it is possible to provide semiconductor devices with improved BV characteristics. In addition, because the junctions of the HVE and HVD active regions have similar structures, it is possible to simultaneously form the source/drain regions of two kinds of transistors with different threshold voltages. Accordingly, it is possible to provide methods of fabricating semiconductors using a reduced number of processes.

Moreover, because the quantity of the contact plugs may be reduced corresponding the size of the ion implantation layer, it is possible to provide a semiconductor device with improved BV characteristics.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A semiconductor device comprising:
a device isolation layer, formed on a semiconductor substrate, configured to define a first active region and a second active region;
a plurality of gate insulation layer patterns, each disposed on the first and second active regions, respectively;
a plurality of gate electrodes, disposed on respective ones of the plurality of gate insulation layer patterns and configured to intersect the first and second active regions and the device isolation layer; and
an ion implantation layer disposed on the semiconductor substrate under the gate electrode of the second active region and spaced apart from the device isolation layer, the ion implantation layer configured to adjust a threshold voltage.

2. The semiconductor device of claim 1, wherein the first active region comprises a high-voltage enhancement active region.

3. The semiconductor device of claim 1, wherein the second active region comprises a high-voltage depletion active region.

4. The semiconductor device of claim 1, further comprising a device isolation ion implantation layer disposed in the semiconductor substrate under the device isolation layer.

5. The semiconductor device of claim 4, wherein the device isolation ion implantation layer comprises impurity ions with a conductivity type substantially identical to that of the semiconductor substrate.

6. The semiconductor device of claim 1, wherein the ion implantation layer is spaced apart from the device isolation layer in at least one of longitudinal and transverse directions of the gate electrode.

7. The semiconductor device of claim 6, wherein the ion implantation layer comprises impurity ions with a conductivity type substantially different from that of the semiconductor substrate.

8. The semiconductor device of claim 1, further comprising a plurality of low-concentration source/drain regions disposed, in the first and second active regions, on both sides of each of the plurality of gate electrodes.

9. The semiconductor device of claim 8, further comprising a plurality of high-concentration source/drain regions disposed in the plurality of low-concentration source/drain regions, respectively.

10. The semiconductor device of claim 9, further comprising a plurality of contact plugs disposed on the plurality of high-concentration source/drain regions.

11. The semiconductor device of claim 10, wherein the plurality of contact plugs are provided in a quantity corresponding to a size of the ion implantation layer.

12. A method of fabricating a semiconductor device, comprising:
forming a device isolation layer defining a first active region and a second active region in a semiconductor substrate;
forming an ion implantation layer at a portion of the surface of the semiconductor substrate in the second active region, the ion implantation layer being spaced apart from the device isolation layer and configured to adjust a threshold voltage;
forming a plurality of gate insulation layer patterns on the first and second active regions; and
forming a plurality of gate electrodes intersecting the first and second active regions and the device isolation layer on the plurality of gate insulation layer patterns,
wherein the ion implantation layer is disposed under the gate electrode of the second active region.

13. The method of claim 12, wherein the first active region comprises a high-voltage enhancement active region.

14. The method of claim 12, wherein the second active region comprises a high-voltage depletion active region.

15. The method of claim 12, further comprising forming a device isolation ion implantation layer in the semiconductor substrate under the device isolation layer.

16. The method of claim 15, wherein the device isolation ion implantation layer comprises impurity ions with a conductivity type substantially identical to that of the semiconductor substrate.

17. The method of claim 12, wherein the ion implantation layer is spaced apart from the device isolation layer in at least one of a longitudinal direction and a transverse direction from the gate electrode.

18. The method of claim 17, wherein the ion implantation layer comprises impurity ions with a conductivity type different from that of the semiconductor substrate.

19. The method of claim 12, further comprising forming a plurality of low-concentration source/drain regions on both sides of the plurality of gate electrodes in the first and second active regions.

20. The method of claim 19, further comprising forming a plurality of high-concentration source/drain regions in the plurality of low-concentration source/drain regions, respectively.

21. The method of claim 20, further comprising forming a plurality of contact plugs on the plurality of high-concentration source/drain regions.

22. The method of claim 21, wherein the plurality of contact plugs are provided in a quantity corresponding to the size of the ion implantation layer.
